(19) United States
(12) Patent Application Publication
(10) Pub. No.: US 2008/0233670 A1
(43) Pub. Date: Sep. 25, 2008

(54) Method for Fabricating a P-I-N Light Emitting Diode Using Cu-Doped P-Type Zno

(75) Inventors: Won-kook Choi, Seoul (KR); Yeon-sik Jung, Seoul (KR)

Correspondence Address: THE RAFFERTY PATENT LAW FIRM, 5641 BURKE CENTRE PKWY, SUITE 100, BURKE, VA, 22015-2259, US

(73) Assignee: KOREA INSTITUTE OF SCIENCE AND TECHNOLOGY, Seoul (KR)

(21) Appl. No.: 12/064,033

(22) PCT Filed: Dec. 9, 2005
(86) PCT No.: PCT/KR2005/004212

§ 371 Date: Feb. 18, 2008

(30) Foreign Application Priority Data
Aug. 23, 2005 (KR) 10-2005-0077109

(51) Int. Cl. H01L 21/00

(52) U.S. Cl. 438/39; 257/E21.121

(57) ABSTRACT

A method of fabricating a p-i-n type light emitting diode using p-type ZnO, and particularly, a technique for fabricating a p-type ZnO thin film doped with copper, a light emitting diode manufactured using the same, and its application to electrical and magnetic devices. The method of fabricating a p-i-n type light emitting diode using p-type ZnO includes depositing a low-temperature ZnO buffer layer on a sapphire single-crystal substrate, depositing an n-type gallium doped ZnO layer on the deposited low-temperature ZnO buffer layer, depositing an intrinsic ZnO thin film on the deposited n-type gallium doped ZnO layer, forming a p-type ZnO thin film layer on the deposited intrinsic ZnO thin film, forming a MESA structure on the p-type ZnO thin film layer through wet etching to obtain a diode structure, and subjecting the diode structure to post-heat treatment.

### TECHNICAL FIELD

The present invention relates, generally, to a method of fabricating a p-i-n type light emitting diode using p-type ZnO, and more particularly, to a novel technique for fabricating a p-type ZnO thin film doped with copper, a light emitting diode (LED) manufactured using the same, and its application to electrical and magnetic devices.

### BACKGROUND ART

In general, since ZnO has an optical bandgap of 3.37 eV near the UV region and a large exciton bonding energy of 60 meV at room temperature, it is receiving attention as a material for optical devices using excitons having higher light efficiency, compared to ZnSe (21 meV) or GaN (28 meV). Further, ZnO has optical gain of 300 cm⁻¹, which is three times the 100 cm⁻¹ of conventionally used GaN, and has saturation velocity (Vₛ) greater than GaN, and is thus preferably used for actual application to electrical devices. Furthermore, ZnO is known to have low threshold energy (Jₜₕ (W/cm²)) for lasing and therefore to be highly efficient. Hence, ZnO is spotlighted as a novel light source in the blue region or near UV region, thanks to the excellent optical properties thereof. However, techniques for fabricating a stable p-type thin film for a basic pn junction structure required for application of LEDs or laser diodes have not yet been established, and actual application thereof is pending.

ZnO, which is classified as an oxide semiconductor among the Group 2˜6 compounds, is typically manufactured into an n-type semiconductor exhibiting n-type conductivity by oxygen vacancy or interstitial zinc defects resulting respectively from oxygen deficiency or excess zinc. On the other hand, a p-type semiconductor is expected to be manufactured using the residual dopant after such properties of ZnO, that is, electrical properties due to the presence of the defects and dopant causing n-type conductivity, are neutralized through compensation. The dopant for use in the manufacture of a p-type ZnO semiconductor should form a hole by substituting for the oxygen of a Group 6 element using a Group 5 element to enable the induction of electrical conductivity. As such, the Group 5 element, including N, P, As or Sb, is known as a dopant suitable for use in the preparation of p-type ZnO.

However, with the aim of fabricating LEDs or laser diodes having high efficiencies using ZnO, the development of techniques for reproducibly manufacturing a p-type ZnO thin film having excellent properties must be realized. Although methods of fabricating a p-type ZnO thin film using the Group 5 element are presently proposed, they have the following problems.

First, the Group 5 element, including N, P, As or Sb, has high solubility at low temperatures, but the solubility thereof is drastically decreased at high temperatures.

Therefore, to prepare ZnO having high quality, methods of manufacturing a ZnO thin film having excellent crystal structure and high electrical mobility through growth of crystals at high temperatures are generally provided. However, it is difficult to prepare a high-concentration p-type dopant due to the low solubility of the Group 5 element upon growth at high temperatures.

Second, the ZnO thin film is composed mainly of a Wurzite crystal structure, and is thus easy to dope with other elements. However, when the Group 5 element is doped with a dopant, it may be present in the form of a compound or cluster having various crystal structures at relatively low temperatures. Such different crystal structures may have varying electrical and engineering properties, and, as well, may act as an n-type dopant, resulting in reverse compensation effects rather than compensation effects. Consequently, it is difficult to control such procedures.

### DISCLOSURE OF INVENTION

### Technical Problem

Accordingly, the present invention has been made keeping in mind the above problems encountered in the related art, and an object of the present invention is to provide a method of fabricating a diode structure using a p-type thin film preparation process, including selecting a dopant that may alleviate the disadvantages of the Group 5 elements and may be dissolved to be highly dense at high temperatures, and then dissolving the selected dopant.

### Technical Solution

In order to accomplish the above object, the present invention provides a method of fabricating a p-i-n type LED using p-type ZnO, comprising a first step of depositing a low-temperature ZnO buffer layer on a sapphire single-crystal substrate; a second step of depositing an n-type gallium doped ZnO layer on the deposited low-temperature ZnO buffer layer; a third step of depositing an intrinsic ZnO thin film on the deposited n-type gallium doped ZnO layer; a fourth step of forming a p-type ZnO thin film layer on the deposited intrinsic ZnO thin film; a fifth step of forming a MESA structure on the p-type ZnO thin film layer through wet etching to obtain a diode structure; and a sixth step of subjecting the diode structure to post-heat treatment.

### Advantageous Effects

The present invention provides a method of fabricating a p-i-n type LED using p-type ZnO. Conventionally, a p-type ZnO thin film was difficult to reproducibly manufacture, attributed to the low solubility at high temperatures and the formation of various intermediate phases at relatively low temperatures of the Group 5 element, including N, P, As or Sb, known as a typical p-type ZnO dopant. However, according to the method of the present invention, a p-type ZnO thin film can be manufactured through post-heat treatment in an oxygen atmosphere under relatively high pressure using a copper dopant. In this way, the stable p-type ZnO thin film can be manufactured, and thus, it is possible to fabricate novel LEDs and laser diodes having high efficiencies in the near UV and visible regions. As well, electrical devices operated at high temperatures can be fabricated.

In addition, through the fabrication of pin or pn UV detectors having fast response times, fire alarms and underwater communication and visible blind detectors can be manufactured.

In addition, it is possible to manufacture a transparent thin film transistor, and therefore new semiconductor and display markets, instead of Si devices, are expected to be created.

### BRIEF DESCRIPTION OF THE DRAWINGS

FIGS. 1A and 1B illustrate patterns as a result of reflection of high energy electron diffraction (RHEED) of a low-temperature buffer layer for deposition of a highly pure ZnO thin film using molecular beam epitaxy (MBE), according to the present invention;

FIGS. 2A to 2C illustrate RHEED patterns of a ZnO thin film doped with high-concentration n-type gallium using MBE, according to the present invention;

FIGS. 3A to 3D illustrate w rocking curves for X-ray ZnO peak varying with carrier concentration of the ZnO thin film doped with high-concentration n-type gallium using MBE, according to the present invention;

FIGS. 4A and 4B illustrate variation curves of carrier concentration and electrical mobility of the ZnO thin film doped with high-concentration n-type gallium using MBE, according to the present invention;

FIGS. 5A to 5C illustrate processes of fabricating an LED using MBE and ion implantation and schematic diode structures; and

FIG. 6 illustrates a current-voltage curve measured after post-heat treatment, according to the present invention.

### BEST MODE FOR CARRYING OUT THE INVENTION

Hereinafter, a detailed description will be given of the present invention, with reference to the appended drawings.

Sapphire single-crystals are relatively inexpensive, and are thus mainly used, along with SiC, to fabricate an optical device made of GaN. However, the mismatch between the sapphire substrate and ZnO is as large as 18.6%, and many defects and significant dislocation occur at the boundary therebetween, resulting in decreased crystal properties of a ZnO thin film for use in an optical device. As a means for overcoming this problem, the use of a buffer layer made of the same material at low temperatures is already known in the art.

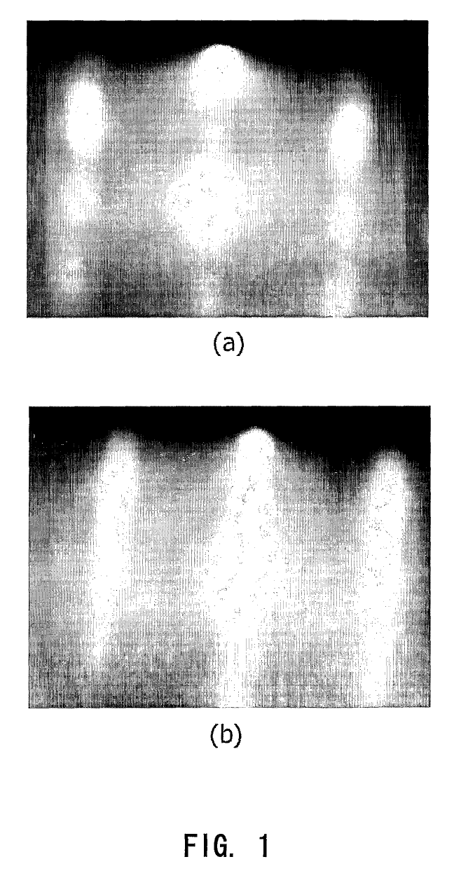

FIGS. 1A and 1B show RHEED patterns of a low-temperature buffer layer for deposition of a highly pure ZnO thin film using MBE. As shown in FIGS. 1A and 1B, in order to grow a ZnO thin film having high quality on the surface of the sapphire single-crystal substrate, the sapphire substrate is maintained at a relatively low temperature of 500° C., and zinc is grown through MBE using a Knudsen cell while oxygen radicals produced by high frequency electrical discharge are supplied to the substrate using a blowing process, which is generally referred to as radical beam assisted molecular beam epitaxy (RA-MBE). The low-temperature buffer ZnO grown thus is illustrated. That is, the buffer layer for the growth of the multi-layered n- and p-type ZnO thin films should have two properties, that is, increase in crystallinity of an upper layer and very low surface roughness for ideal physical adhesion at the boundary between multi-layered thin films.

Through the RHEED pattern, the growth mode of the buffer layer may be determined by varying the thickness thereof from 5 to 20 nm. As is apparent from FIG. 1A, when the buffer layer is 8 nm thick, the buffer layer is seen to grow in a two-dimensional mode through the RHEED pattern which is very streaky and clear. However, it appears that the crystallinity of the ZnO thin film grown thereon is not complete, as desired.

Further, as in FIG. 1B, when the buffer layer is 15 nm thick, dot images are observed in the RHEED pattern, leading to a three-dimensional growth mode. Then, when the buffer layer is heat treated at 800° C. for 30 min in a vacuum, the streaks of the RHEED pattern vary. Therefore, the undoped ZnO thin film deposited on such a buffer layer at a substrate temperature of 720˜760° C. has excellent peak width at half height of w rocking curve for ZnO among X-ray diffraction peaks, of 86˜92 arcsec. In addition, the undoped ZnO thin film has surface roughness less than 1.9 nm, and is thus very flat. That is, the crystallinity of the ZnO thin film is greatly increased by the thickness of the buffer layer for the ZnO thin film and the vacuum heat treatment thereof.

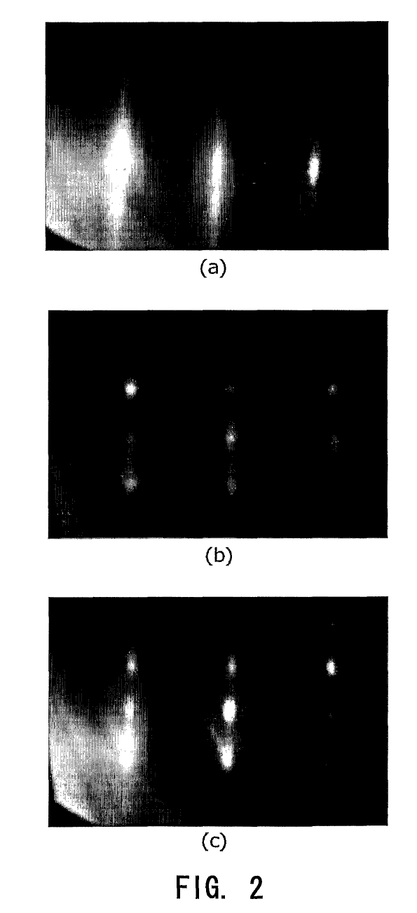

FIGS. 2A to 2C show RHEED patterns of a ZnO thin film doped with high concentration n-type gallium using MBE. In FIGS. 2A to 2C, variation in surface roughness depending on the concentration of gallium (Ga) serving as a dopant is illustrated, in order to grow a high-concentration n-type ZnO thin film required for an LED on the same buffer layer, which is 15 nm thick. As such, the reason why gallium is used is that gallium can effectively substitute for Zn, because it has an ion radius of 62 pm (1 pm=10⁻¹² m), which is highly similar to that of Zn (74 pm), in addition to Al (50 pm) and In (81 pm), and also has a covalent length of Ga—O of 1.92 Å which is highly similar to that of Zn—O (1.97 Å), in addition to Al—O (2.3 Å) and In—O (2.1 Å).

FIG. 2A is the RHEED pattern showing surface flatness upon growth of a Ga:ZnO film having a carrier concentration of nₑ=1×10¹⁸/cm³. From the brightly shining long streaky RHEED pattern, it appears that the surface of the Ga:ZnO film is grown to be very flat. That is, this film grows in two dimensions.

FIGS. 2B and 2C are the RHEED patterns of the Ga:ZnO films having nₑ=1×10¹⁹/cm³ and nₑ=2.5×10²⁰/cm³. Unlike FIG. 2A, bright dotty images are seen to overlap the long streaky image. Such dotty images result from the diffraction of the electron beam by three-dimensional particles upon the growth of the thin film, which directly proves that three-dimensional growth is realized by forming atoms into a small core, which is then grown to a particle boundary, upon the deposition of the thin film, instead of two-dimensional growth. However, the three-dimensional growth mode negatively affects the fabrication of an LED composed of a multi-layered thin film structure, that is, mainly causes short circuits of electrical devices due to the concentration of electric field or of current flow. Further, upon light emission, light is scattered, resulting in decreased light strength. Thus, the very flat two-dimensional thin film of Ga:ZnO (nₑ=1×10¹⁸/cm³) as in FIG. 2A is preferably used as an n-type ZnO layer.

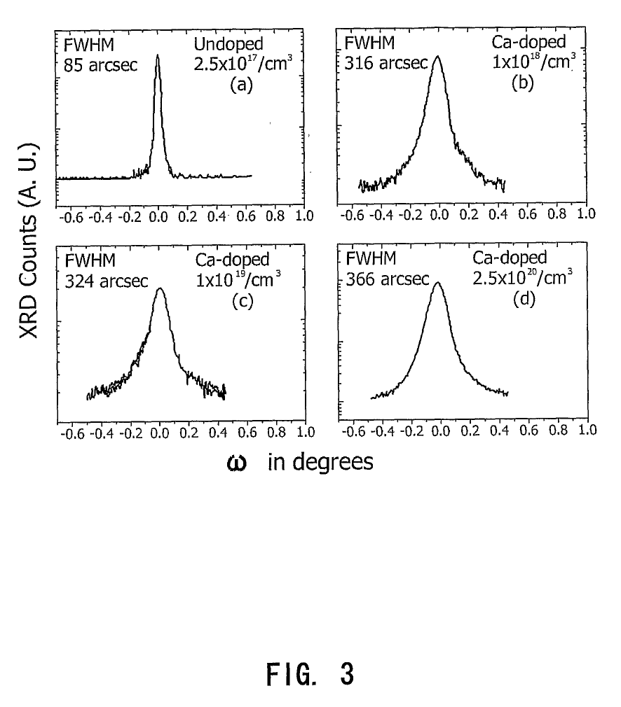

FIGS. 3A to 3D show w rocking curves for X-ray ZnO peaks depending on the carrier concentration of the ZnO thin film doped with high-concentration n-type Ga using MBE according to the present invention. As shown in FIGS. 3A to 3D, the w rocking curves for X-ray diffraction peaks of ZnO are compared by measuring the peak width at half heights thereof.

The thin film without Ga has a peak width at half height as small as 85 arcsec, as shown in FIG. 3A, in which the ZnO thin film is epitaxially grown at the single-crystal level on the sapphire substrate.

As is apparent from FIG. 3B, Ga:ZnO (nₑ=1×10¹⁸/cm³) has 316 arcsec, which is about 4 times the peak width at half height of the thin film of FIG. 3A. This is because Ga is substituted for Zn, thus partially changing the bonding length with oxygen and totally degrading the crystallinity of ZnO to a slight extent. The increase in peak width at half height is commonly observed upon doping. As the carrier concentration is increased to nₑ=1×10¹⁹/cm³ of FIG. 3C and nₑ=2.5×10²⁰/cm³ of FIG. 3D, the peak widths at half height of the w rocking curve are slightly increased to 324 arcsec and 366 arcsec.

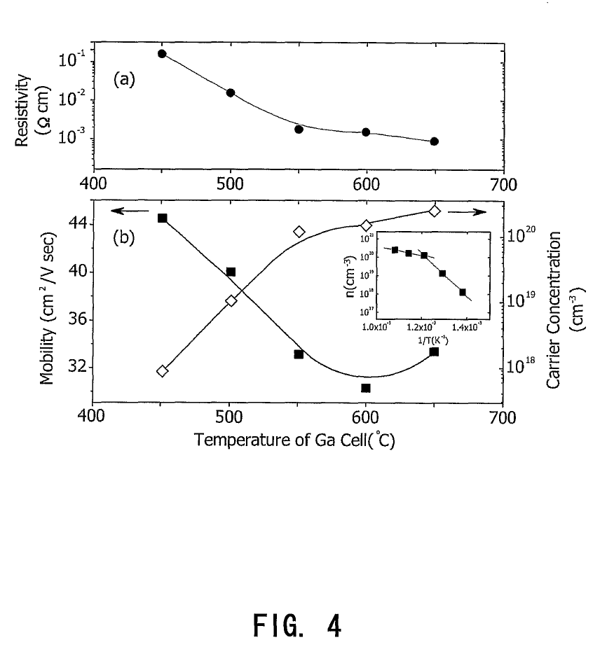

FIGS. 4A and 4B show the variation curves of carrier concentration and electrical mobility of a ZnO thin film doped with high-concentration n-type Ga using MBE according to the present invention. In FIGS. 4A and 4B, variation in electrical mobility depending on resistivity and carrier concentration is shown.

FIG. 4A shows the variation in resistivity. Ga:ZnO (nₑ=1×10¹⁸/cm³) has the resistivity of 0.15 Wcm. As such, if the carrier concentration is increased, resistivity is greatly decreased. Thus, the resistivity of Ga:ZnO (nₑ=2.5×10²⁰/cm³) is decreased to 10⁻³ Wcm.

In this way, the reason why the resistivity is drastically decreased in proportion to an increase in carrier concentration is based on the Burstein-Moss effect, in which excess electrons enter the conduction band when the carrier concentration is increased, and thus such electrons positioned on the conduction band easily function to increase electrical conductivity.

FIG. 4B shows the variation in electrical mobility depending on the carrier concentration. Ga:ZnO (nₑ=1×10¹⁸/cm³) has relatively high mobility of about 45 cm²/Vs. However, when the carrier concentration is increased, the electrons intensively collide with each other, thus slightly decreasing the mobility. In the case of the thin film of Ga:ZnO (nₑ=1×10²⁰/cm³), the mobility is decreased to 30 cm²/Vs.

From the results of FIGS. 2 to 4, it can be found that Ga:ZnO (nₑ=1×10¹⁸/cm³), having very low surface roughness, resistivity of 0.1 Wcm, and excellent electrical mobility of 45 cm²/Vs, is preferably used as the n-type ZnO thin film for use in the fabrication of multi-layered LEDs.

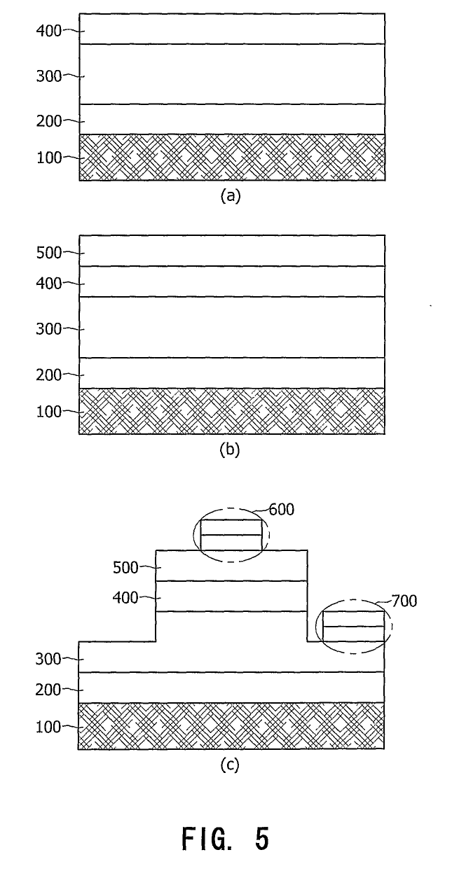

FIGS. 5A to 5C show the LED fabrication processes using MBE and ion implantation and schematic diode structures. As shown in FIGS. 5A to 5C, the process of fabricating the p-type intrinsic n-type LED using ZnO is provided.

On a sapphire single-crystal substrate 100, a low-temperature ZnO buffer layer 200 of FIG. 1A or 1B is deposited, and then Ga:ZnO (nₑ=1×10¹⁸/cm³) of FIG. 2A is deposited to a thickness of 550˜650 nm. The low-temperature ZnO buffer layer 300 is preferably 600 nm thick.

Subsequently, an intrinsic ZnO thin film 400 having a thickness of about 350˜450 nm, that is, a ZnO thin film without n-type or p-type dopants, is deposited. Preferably, the intrinsic ZnO thin film 400 is 400 nm thick.

As seen in FIG. 5B, the intrinsic ZnO thin film layer 400 is doped with a copper (Cu) ion through ion implantation for p-type doping to form a doping layer 500. At this time, the copper ion is extracted from SNICS (Sputtered Negative Ion Cesium Exchange Source) and accelerated to 80-120 keV to be ion implanted. The average implantation distance of the copper ion is measured to be about 100-120 nm using a computer code (SRIM-2003).

Then, the copper ion is substituted for the zinc metal and thus should be present in the form of Cu⁺ (Cu₂O) instead of Cu²⁺ (CuO), so that the implanted copper ion functions as a p-type ZnO. To this end, a post-heat treatment procedure is required. In the present invention, among various heat treatment conditions, the post-heat treatment is conducted in an oxygen atmosphere to attain p-type doping properties of copper ions. That is, even in the intrinsic ZnO, since the amount of oxygen is commonly insufficient, many oxygen vacancies are present and act as a main factor exhibiting n-type properties. When the copper ions are implanted in the intrinsic ZnO thin film, oxygen in the intrinsic ZnO thin film may escape to a vacuum upon ion implantation. In addition, defects generated by disrupting excellent crystallinity during ion implantation may cause n-type properties. Therefore, the p-type properties of the copper dopant are intended to be restored through rapid post-heat treatment in an oxygen atmosphere for compensation of n-type factors and for restoration of crystallinity. The post-heat treatment is conducted at 800° C. for 1˜10 min in an atmosphere where oxygen partial pressure is 100˜300 Torr.

In order to confirm the fabricated LED, a MESA structure is manufactured through a wet etching process. In this case, ohmic contact of a Ti/Au layer 700 and an Ni/Au layer 600 serving as the n-type and p-type electrical contact materials, respectively, is confirmed by means of an electron beam evaporator, after which current-voltage properties are measured.

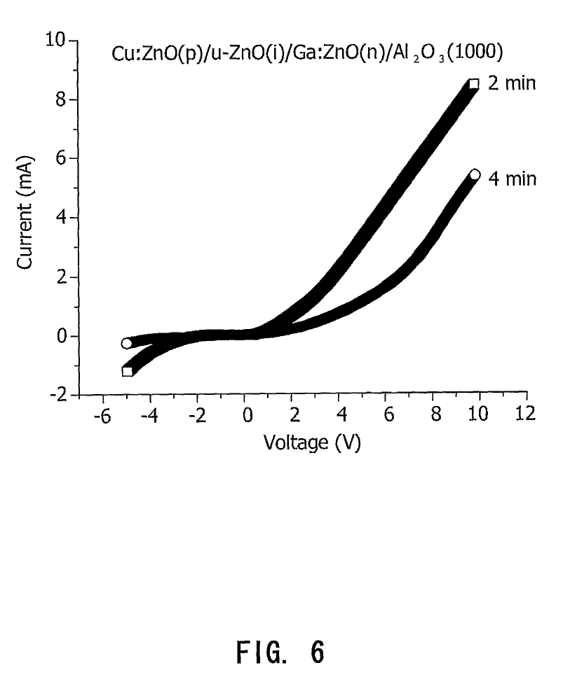

FIG. 6 shows the current-voltage (I-V) curve measured after the post-heat treatment according to the present invention. As shown in FIG. 6, the current-voltage properties are measured after the heat treatment at an oxygen partial pressure of 100 Torr for each of 2 and 4 min. Since the two curves are linear I-V curves, the copper ion is seen to effectively function as a p-type dopant. Upon heat treatment for 2 min, the leakage current is drastically increased at an inverse voltage of −3 V, negating excellent pn junction diode properties. However, when the heat treatment is conducted for 4 min, superior inverse voltage properties are obtained, a turn-on voltage in a forward direction is about 4 V, and large current of about 5 mA may flow upon the application of a voltage of 10 V, thus manifesting outstanding current-voltage properties. From the I-V curve, the copper dopant, which has not yet been known to date, is confirmed to be a dopant enabling the exhibition of excellent electrical properties of p-type ZnO. In order to electrically activate the copper dopant like the p-type ZnO, it is found that post-heat treatment must be conducted in an oxygen atmosphere under relatively high pressure.

### INDUSTRIAL APPLICABILITY

As described hereinbefore, the present invention provides a method of fabricating a p-i-n type LED using p-type ZnO. Conventionally, a p-type ZnO thin film was difficult to reproducibly manufacture, attributed to the low solubility at high temperatures and the formation of various intermediate phases at relatively low temperatures of the Group 5 element, including N, P, As or Sb, known as a typical p-type ZnO dopant.

However, according to the method of the present invention, a p-type ZnO thin film can be manufactured through post-heat treatment in an oxygen atmosphere under relatively high pressure using a copper dopant. In this way, the stable p-type ZnO thin film can be manufactured, and thus, it is possible to fabricate novel LEDs and laser diodes having high efficiencies in the near UV and visible regions. As well, electrical devices operated at high temperatures can be fabricated.

In addition, through the fabrication of pin or pn UV detectors having fast response times, fire alarms and underwater communication and visible blind detectors can be manufactured.

In addition, it is possible to manufacture a transparent thin film transistor, and therefore new semiconductor and display markets, instead of Si devices, are expected to be created.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

1. A method of fabricating a p-i-n type light emitting diode using p-type ZnO, comprising:
a first step of depositing a low-temperature ZnO buffer layer on a sapphire single-crystal substrate;
a second step of depositing an n-type gallium doped ZnO layer on the deposited low-temperature ZnO buffer layer;
a third step of depositing an intrinsic ZnO thin film on the deposited n-type gallium doped ZnO layer;
a fourth step of forming a p-type ZnO thin film layer on the deposited intrinsic ZnO thin film;
a fifth step of forming a MESA structure on the p-type ZnO thin film layer through wet etching, to obtain a diode structure; and
a sixth step of subjecting the diode structure to post-heat treatment.

2. The method according to claim 1, wherein the n-type gallium doped ZnO layer is 550˜650 nm thick.

3. The method according to claim 1, wherein the intrinsic ZnO thin film is 350˜450 nm thick.

4. The method according to claim 1, wherein the p-type ZnO thin film layer is formed of copper.

5. The method according to claim 1, wherein the post-heat treatment is conducted in an oxygen atmosphere.

6. The method according to claim 5, wherein the post-heat treatment is conducted in an atmosphere of 100˜300 Torr.

7. The method according to claim 1, wherein the post-heat treatment is conducted at 800° C. for 1˜10 min.
